(19) United States
(12) Patent Application Publication
(10) Pub. No.: US 2026/0344105 A1
(43) Pub. Date: Oct. 29, 2026

(54) PHOTODETECTOR

(71) Applicant: HAMAMATSU PHOTONICS K.K., Hamamatsu-shi, Shizuoka (JP)

(72) Inventors: Tomohiro HOSOYAMA, Hamamatsu-shi, Shizuoka (JP); Takayuki IKEYA, Hamamatsu-shi, Shizuoka (JP); Noriyuki IGUCHI, Hamamatsu-shi, Shizuoka (JP)

(73) Assignee: HAMAMATSU PHOTONICS K.K., Hamamatsu-shi, Shizuoka (JP)

(21) Appl. No.: 19/110,917

(22) PCT Filed: Oct. 11, 2023
(86) PCT No.: PCT/JP2023/036843

§ 371 Date: Mar. 12, 2025

(30) Foreign Application Priority Data
Oct. 13, 2022 (JP) 2022-164787

(51) Int. Cl. H10F 77/40; H10F 77/50

(52) U.S. Cl. CPC H10F 77/407; H10F 77/50

(57) ABSTRACT

A photodetector includes a package having a bottom wall portion and a window portion facing each other, a light receiving element disposed on the bottom wall portion in the package, a light transmitting member disposed on the light receiving element in the package, and an optical filter member disposed on the light transmitting member in the package. The light receiving element has a light receiving region including a plurality of light receiving units. When viewed from a direction in which the bottom wall portion and the window portion face each other, an outer edge of the light receiving element is positioned inside an outer edge of the optical filter member.

### TECHNICAL FIELD

The present disclosure relates to a photodetector.

### BACKGROUND ART

There is known a photodetector including a package having a bottom wall portion and a window portion facing each other and a light receiving element disposed on the bottom wall portion in the package, in which the window portion is constituted by an optical filter member (see, for example, Patent Literature 1).

### CITATION LIST

### Patent Literature

Patent Literature 1: Japanese Unexamined Patent Publication No. H3-27554

### SUMMARY OF INVENTION

### Technical Problem

In the photodetector described above, since the window portion is constituted by the optical filter member in the package, only light to be detected can be incident on the light receiving element. On the other hand, for example, when an attempt is made to increase a size of an opening closed by the window portion in the package, it is naturally necessary to increase a size of the optical filter member. However, in general, it is desirable to avoid increasing a size of an expensive optical filter member. That is, when the window portion is constituted by the optical filter member in the package, a degree of freedom of a shape of the package is restricted.

An object of the present disclosure is to provide a photodetector capable of accurately detecting light to be detected while securing a degree of freedom of a shape of a package.

### Solution to Problem

A photodetector according to one aspect of the present disclosure is [1] “a photodetector including a package having a bottom wall portion and a window portion facing each other, a light receiving element disposed on the bottom wall portion in the package, a light transmitting member disposed on the light receiving element in the package, and an optical filter member disposed on the light transmitting member in the package, in which the light receiving element includes a light receiving region including a plurality of light receiving units, and when viewed from a direction in which the bottom wall portion and the window portion face each other, an outer edge of the light receiving element is positioned inside an outer edge of the optical filter member”.

In the photodetector, the light receiving element is disposed on the bottom wall portion in the package, and the optical filter member is disposed on the light receiving element in the package. As a result, for example, the degree of freedom of the shape of the package is secured such that it is not necessary to reduce the size of the opening closed by the window portion in the package. Further, in the photodetector, when viewed from a direction in which the bottom wall portion and the window portion face each other, the outer edge of the light receiving element is positioned inside the outer edge of the optical filter member. As a result, a probability that light is incident on the light receiving element via the optical filter member increases. As described above, according to the photodetector, it is possible to accurately detect the light to be detected while securing the degree of freedom of the shape of the package.

The photodetector according to one aspect of the present disclosure may be [2] “the photodetector according to the above [1], in which, when viewed from the direction in which the bottom wall portion and the window portion face each other, a distance between an outer edge of the light receiving region and the outer edge of the light receiving element is larger than a distance between the outer edge of the light receiving element and the outer edge of the optical filter member”. According to the photodetector, the light obliquely incident on the light receiving element without passing through the optical filter member can be prevented from being incident on the light receiving region, and the light to be detected can be detected more accurately.

The photodetector according to one aspect of the present disclosure may be [3] “the photodetector according to the above [1] or [2],in which, when viewed from the direction in which the bottom wall portion and the window portion face each other, an outer edge of the light transmitting member is positioned inside the outer edge of the optical filter member”. According to the photodetector, the light obliquely incident on the light transmitting member without passing through the optical filter member can be prevented from being guided by the light transmitting member and being incident on the light receiving element, and the light to be detected can be detected more accurately.

The photodetector according to one aspect of the present disclosure may be [4] “the photodetector according to the above [3] further including an adhesive member disposed between the light transmitting member and the optical filter member”. According to the photodetector, in a case where an adhesive (having fluidity and cured after adhesion) is used as the adhesive member at the time of manufacturing the photodetector, since the adhesive is likely to remain at a corner portion between the side surface of the light transmitting member and the front surface of the optical filter member on the light transmitting member side, the optical filter member can be firmly fixed on the light transmitting member while suppressing unnecessary spread of the adhesive.

The photodetector according to one aspect of the present disclosure may be [5] “the photodetector according to any one of the above to [4] further including a circuit element disposed between the bottom wall portion and the light receiving element”. According to the photodetector, it is possible to reduce the size of the photodetector when viewed from the direction in which the bottom wall portion and the window portion face each other.

The photodetector according to one aspect of the present disclosure may be [6] “the photodetector according to the above [5] further including a plurality of bumps electrically and physically connecting the circuit element and the light receiving element”. According to the photodetector, it is possible to improve the responsiveness of the electric signal between the circuit element and the light receiving element.

The photodetector according to one aspect of the present disclosure may be [7] “the photodetector according to the above [6] further including a first resin member disposed between the circuit element and the light receiving element, in which the first resin member reaches a side surface of the light transmitting member via a side surface of the light receiving element”. According to the photodetector, not only fixation between the circuit element and the light receiving element but also fixation between the light receiving element and the light transmitting member can be maintained in a reliable state.

The photodetector according to one aspect of the present disclosure may be [8] “the photodetector according to the above [5], in which the circuit element and the light receiving element are electrically and physically connected by direct bonding”. According to the photodetector, it is possible to improve the responsiveness of the electric signal between the circuit element and the light receiving element.

The photodetector according to one aspect of the present disclosure may be [9] “the photodetector according to any one of the above to [8] further including a wire extending between a terminal of the bottom wall portion and a terminal of the circuit element, and a second resin member covering the wire”. According to the photodetector, it is possible to apply the high voltage to the wire while suppressing unintended energization.

The photodetector according to one aspect of the present disclosure may be [10] “the photodetector according to the above [9], in which the wire is a wire for applying a power supply voltage to the light receiving element”. According to the photodetector, it is possible to apply the power supply voltage to the light receiving element while suppressing unintended energization by the wire.

The photodetector according to one aspect of the present disclosure may be [11] “the photodetector according to any one of the above [1] to [10], in which the optical filter member includes a light transmitting substrate and an optical filter film formed on a front surface of the light transmitting substrate on the light transmitting member side”. According to the photodetector, for example, as compared with a case where the optical filter film is formed on the front surface of the light transmitting substrate opposite to the light transmitting member, a probability that light is incident on the light receiving element via the optical filter film can be increased, and the light to be detected can be detected more accurately.

The photodetector according to one aspect of the present disclosure may be [12] “the photodetector according to any one of the above [1] to [11], in which, when viewed from the direction in which the bottom wall portion and the window portion face each other, an outer edge of a light transmitting region in the window portion is positioned outside the outer edge of the optical filter member”. According to the photodetector, the visibility in the package via the window portion can be improved, and the inspection in the package can be appropriately performed.

The photodetector according to one aspect of the present disclosure may be [13] “the photodetector according to any one of the above [1] to [12], in which a distance between an outer edge of the light receiving region and the outer edge of the light receiving element when viewed from the direction in which the bottom wall portion and the window portion face each other is larger than a thickness of the light receiving element in the direction in which the bottom wall portion and the window portion face each other”. According to the photodetector, the light obliquely incident on the light receiving element without passing through the optical filter member can be prevented from being incident on the light receiving region, and the light to be detected can be detected more accurately.

The photodetector according to one aspect of the present disclosure may be [14] “the photodetector according to any one of the above [1] to [13], in which a distance between an outer edge of the light receiving region and the outer edge of the optical filter member when viewed from the direction in which the bottom wall portion and the window portion face each other is larger than a thickness of the light transmitting member in the direction in which the bottom wall portion and the window portion face each other”. According to the photodetector, the light obliquely incident on the light receiving element without passing through the optical filter member can be prevented from being incident on the light receiving region, and the light to be detected can be detected more accurately.

### Advantageous Effects of Invention

According to the present disclosure, it is possible to provide the photodetector capable of accurately detecting the light to be detected while securing the degree of freedom of the shape of the package.

### BRIEF DESCRIPTION OF DRAWINGS

FIG. 1 is a plan view of a photodetector according to an embodiment.

FIG. 2 is a sectional view of the photodetector taken along line II-II illustrated in FIG. 1.

FIG. 3 is an enlarged view of a part of the photodetector illustrated in FIG. 2.

FIG. 4 is a diagram illustrating a process of manufacturing the photodetector illustrated in FIG. 1.

FIG. 5 is a diagram illustrating a process of manufacturing the photodetector illustrated in FIG. 1.

### DESCRIPTION OF EMBODIMENTS

Hereinafter, embodiments of the present disclosure will be described in detail with reference to the accompanying drawings. Note that, in the drawings, the same or corresponding parts are denoted by the same reference signs, and redundant description will be omitted.

### Configuration of Photodetector

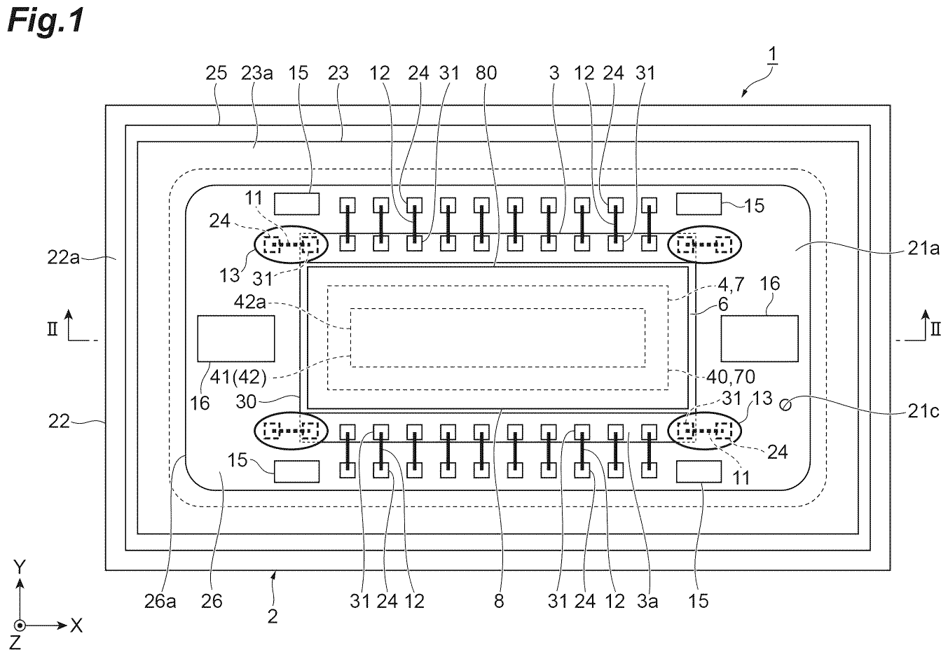

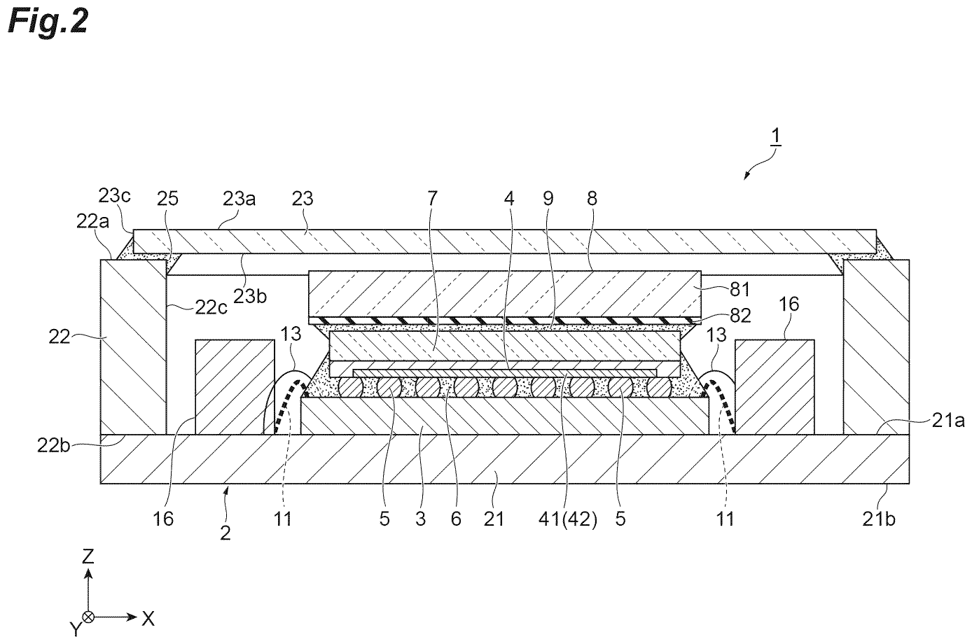

As illustrated in FIGS. 1 and 2, a photodetector 1 includes a package 2. The package 2 includes a bottom wall portion 21, a side wall portion 22, and a window portion 23. The bottom wall portion 21 and the window portion 23 face each other in a Z direction via the side wall portion 22. When viewed from the Z direction, the package 2 has, for example, a rectangular shape in which an X direction and a Y direction are a long side direction and a short side direction, respectively. As an example, a width of the package 2 in the X direction is about 20 mm, a width of the package 2 in the Y direction is about 10 mm, and a width of the package 2 in the Z direction is about 3 mm. Note that, the Z direction, the X direction, and the Y direction are directions orthogonal to each other.

The bottom wall portion 21 is a substrate on which a plurality of wirings (not illustrated) are provided. The substrate is formed in a rectangular plate shape by, for example, glass fiber and epoxy resin. The bottom wall portion 21 is not transparent to light (including visible light) including light to be detected. The bottom wall portion 21 has a front surface 21a on one side and a front surface 21b on the other side in the Z direction. One end portion of each wiring is disposed as a terminal 24 on the front surface 21a, and the other end portion of each wiring is disposed as a terminal (not illustrated) on the front surface 21b. That is, the bottom wall portion 21 has the plurality of terminals 24 disposed on the front surface 21a. A through-hole 21c is formed in the bottom wall portion 21. The through-hole 21c communicates a space inside the package 2 and a space outside the package 2.

The side wall portion 22 is a frame body extending along an outer edge of the front surface 21a of the bottom wall portion 21. The side wall portion 22 is formed in a rectangular frame shape by, for example, glass fiber and epoxy resin. The side wall portion 22 is not transparent to light including the light to be detected. The side wall portion 22 has an end surface 22a on one side and an end surface 22b on the other side in the Z direction. The side wall portion 22 is fixed to the bottom wall portion 21 by an adhesive member (not illustrated) disposed between the front surface 21a of the bottom wall portion 21 and the end surface 22b of the side wall portion 22.

The window portion 23 is a substrate transparent to light including the light to be detected. The window portion 23 is formed in a rectangular plate shape by, for example, glass. The window portion 23 has a front surface 23a on one side and a front surface 23b on the other side in the Z direction. The window portion 23 is fixed to the side wall portion 22 by an adhesive member 25 disposed between the end surface 22a of the side wall portion 22 and the front surface 23b of the window portion 23. When viewed from the Z direction, a side surface 23c of the window portion 23 is positioned on the end surface 22a of the side wall portion 22. The adhesive member 25 reaches a corner portion between the front surface 23b of the window portion 23 and an inner side surface 22c of the side wall portion 22 and a corner portion between the side surface 23c of the window portion 23 and the end surface 22a of the side wall portion 22 from a region between the end surface 22a of the side wall portion 22 and the front surface 23b of the window portion 23. Note that, an antireflection film (not illustrated) is formed on each of the front surfaces 23a and 23b of the window portion 23. The antireflection film may be formed only on the front surface 23a of the window portion 23, or may be formed only on the front surface 23b of the window portion 23.

As illustrated in FIGS. 1, 2, and 3, in the package 2, a circuit element 3 is disposed on the bottom wall portion 21. The circuit element 3 is an element having a signal processing circuit. The circuit element 3 is, for example, a transimpedance amplifier (TIA). The circuit element 3 has, for example, a rectangular plate shape in which the X direction and the Y direction are a long side direction and a short side direction, respectively, and the Z direction is a thickness direction. The circuit element 3 has a front surface 3a on one side and a front surface 3b on the other side in the Z direction. The circuit element 3 is fixed to the bottom wall portion 21 by an adhesive member (not illustrated) disposed between the front surface 21a of the bottom wall portion 21 and the front surface 3b of the circuit element 3. The circuit element 3 has a plurality of terminals 31 disposed on the front surface 3a.

In the package 2, a light receiving element 4 is disposed on the circuit element 3. That is, the light receiving element 4 is disposed on the bottom wall portion 21 via the circuit element 3. In other words, the circuit element 3 is disposed between the bottom wall portion 21 and the light receiving element 4. The light receiving element 4 is a back-incident optical semiconductor element having sensitivity to light including the light to be detected. The light receiving element 4 is, for example, a back-incident avalanche photodiode (Si-APD) array. The light receiving element 4 has, for example, a rectangular plate shape in which the X direction and the Y direction are a long side direction and a short side direction, respectively, and the Z direction is a thickness direction. The light receiving element 4 has a front surface 4a on one side and a front surface 4b on the other side in the Z direction. As an example, a thickness of the light receiving element 4 is about 50 μm.

The light receiving element 4 has a light receiving region 42 including a plurality of light receiving units 41. When viewed from the Z direction, the light receiving region 42 has, for example, a rectangular shape in which the X direction and the Y direction are a long side direction and a short side direction, respectively. The plurality of light receiving units 41 are two-dimensionally disposed along the front surface 4b. Each light receiving unit 41 includes, for example, an APD. Note that, each light receiving unit 41 may include, for example, a photodiode (PD) or a silicon photomultiplier (SiPM).

The light receiving element 4 is electrically and physically connected to the circuit element 3 by a plurality of bumps 5. The plurality of bumps 5 are disposed between the plurality of terminals (not illustrated) disposed on the front surface 3a of the circuit element 3 and a plurality of terminals (not illustrated) disposed on the front surface 4b of the light receiving element 4. Each bump 5 electrically and physically connects terminals facing each other in the Z direction. A resin member (first resin member) 6 is disposed between the circuit element 3 and the light receiving element 4 so as to cover each bump 5. The resin member 6 is, for example, an underfill resin member.

In the package 2, a light transmitting member 7 is disposed on the light receiving element 4. The light transmitting member 7 is a substrate transparent to light including the light to be detected. The light transmitting member 7 has, for example, a rectangular plate shape in which the X direction and the Y direction are a long side direction and a short side direction, respectively, and the Z direction is a thickness direction. The light transmitting member 7 is formed in a rectangular plate shape by, for example, glass. The light transmitting member 7 has a front surface 7a on one side and a front surface 7b on the other side in the Z direction. The light transmitting member 7 is fixed to the light receiving element 4 by direct bonding between the front surface 4a of the light receiving element 4 and the front surface 7b of the light transmitting member 7. When viewed from the Z direction, an outer edge 70 of the light transmitting member 7 coincides with an outer edge 40 of the light receiving element 4. A thickness of the light transmitting member 7 is larger than a thickness of the light receiving element 4. As an example, the thickness of the light transmitting member 7 is about 300 μm. Note that, the light transmitting member 7 may be fixed to the light receiving element 4 by a light transmitting adhesive member (for example, an adhesive, an adhesive sheet, or the like) disposed between the front surface 4a of the light receiving element 4 and the front surface 7b of the light transmitting member 7.

As an example, the light receiving element 4 and the light transmitting member 7 described above are manufactured as follows. First, a first wafer including a portion to be each of a plurality of light receiving elements 4 disposed two-dimensionally and a second wafer including a portion to be each of a plurality of light transmitting members 7 disposed two-dimensionally are prepared. Subsequently, the second wafer is bonded to the first wafer. Subsequently, the first wafer and the second wafer bonded to each other are diced for each portion to be each of the plurality of light receiving elements 4. As a result, the light receiving element 4 and the light transmitting member 7 bonded to each other are obtained. In the light receiving element 4 and the light transmitting member 7, the light transmitting member 7 functions as a support substrate of the thinned light receiving element 4.

When viewed from the Z direction, the outer edge 40 of the light receiving element 4 and the outer edge 70 of the light transmitting member 7 are positioned inside an outer edge 30 of the circuit element 3. The plurality of terminals 31 are disposed on the front surface 3a of the circuit element 3 so as to be positioned outside the outer edge 40 of the light receiving element 4 and the outer edge 70 of the light transmitting member 7 when viewed from the Z direction. The resin member 6 does not reach the plurality of terminals 31 on the front surface 3a of the circuit element 3, but reaches a side surface 7c of the light transmitting member 7 via a side surface 4c of the light receiving element 4. A plurality of wires 11 and a plurality of wires 12 are connected to the plurality of terminals 31. Each wire 11 is a wire for applying a power supply voltage to the light receiving element 4, and extends between the terminal 24 and the terminal 31 corresponding to each other. Each wire 12 is a wire for outputting a detection signal, and extends between the terminal 24 and the terminal 31 corresponding to each other. Each wire 11 is covered with a resin member (second resin member) 13. Note that, the resin member 6 may reach the side surface 4c of the light receiving element 4 and may not reach the side surface 7c of the light transmitting member 7.

In the package 2, an optical filter member 8 is disposed on the light transmitting member 7. The optical filter member 8 has, for example, a rectangular plate shape in which the X direction and the Y direction are a long side direction and a short side direction, respectively, and the Z direction is a thickness direction. The optical filter member 8 has a front surface 8a on one side and a front surface 8b on the other side in the Z direction. The optical filter member 8 is fixed to the light transmitting member 7 by an adhesive member 9 disposed between the front surface 7 a of the light transmitting member 7 and the front surface 8b of the optical filter member 8. The adhesive member 9 is transparent to light including the light to be detected.

The optical filter member 8 includes a light transmitting substrate 81 and an optical filter film 82. The light transmitting substrate 81 is a substrate transparent to light including the light to be detected. The light transmitting substrate 81 has, for example, a rectangular plate shape in which the X direction and the Y direction are a long side direction and a short side direction, respectively, and the Z direction is a thickness direction. The light transmitting substrate 81 is formed in a rectangular plate shape by, for example, glass. The light transmitting substrate 81 has a front surface 81a on one side and a front surface (a surface of the light transmitting substrate on the light transmitting member side) 81b on the other side in the Z direction. A thickness of the light transmitting substrate 81 is larger than ae thickness of the light transmitting member 7. As an example, the thickness of the light transmitting substrate 81 is about 500 μm. The optical filter film 82 is formed on the front surface 81b of the light transmitting substrate 81. The optical filter film 82 transmits only the light to be detected. The optical filter film 82 is, for example, a band pass filter film. As an example, a thickness of the optical filter film 82 is about 0.5 μm. An antireflection film (not illustrated) is formed on the front surface 81a of the light transmitting substrate 81. Note that, the thickness of the light transmitting substrate 81 may be equal to or less than the thickness of the light transmitting member 7. In addition, the antireflection film may not be formed on the front surface 81a of the light transmitting substrate 81.

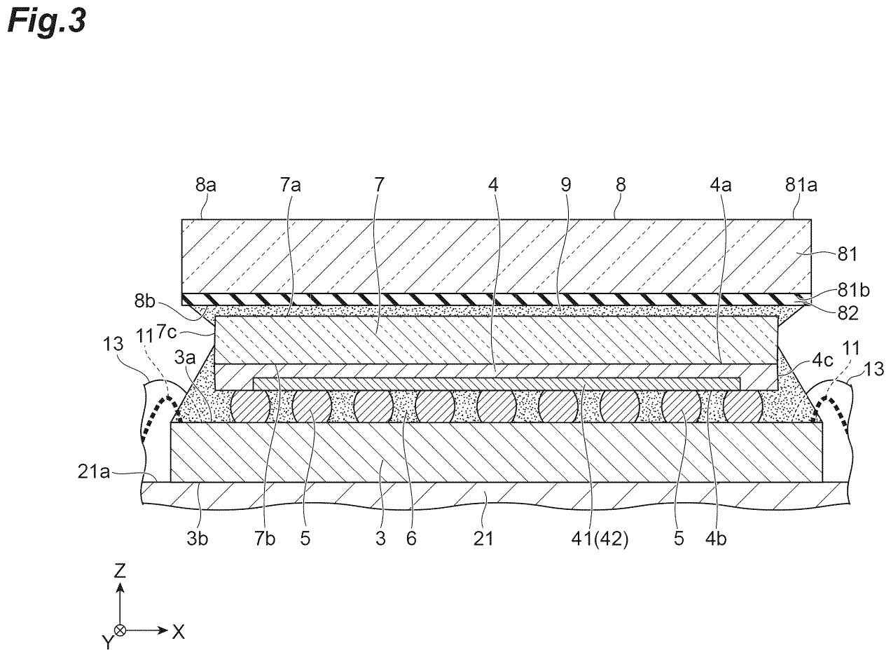

As illustrated in FIG. 1, when viewed from the Z direction, the outer edge 40 of the light receiving element 4 and the outer edge 70 of the light transmitting member 7 are positioned inside an outer edge 80 of the optical filter member 8. As illustrated in FIG. 3, the adhesive member 9 reaches a corner portion between the front surface 8b of the optical filter member 8 and the side surface 7c of the light transmitting member 7 from a region between the front surface 7a of the light transmitting member 7 and the front surface 8b of the optical filter member 8.

As illustrated in FIG. 1, when viewed from the Z direction, a distance between an outer edge 42a of the light receiving region 42 and the outer edge 40 of the light receiving element 4 is larger than a distance between the outer edge 40 of the light receiving element 4 and the outer edge 80 of the optical filter member 8. The distance between the outer edge 42a of the light receiving region 42 and the outer edge 40 of the light receiving element 4 when viewed from the Z direction is “a distance between one side of the outer edge 42a and one side of the outer edge 40 parallel to the one side of the outer edge 42a (that is, one side of the outer edge 40 opposite to the light receiving region 42 side with respect to the one side of the outer edge 42a)” when viewed from the Z direction, and means a minimum value of different distances in a case where the distance differs depending on the side. The distance between the outer edge 40 of the light receiving element 4 and the outer edge 80 of the optical filter member 8 when viewed from the Z direction is “a distance between one side of the outer edge 40 and one side of the outer edge 80 parallel to the one side of the outer edge 40 (that is, one side of the outer edge 80 opposite to the light receiving element 4 side with respect to the one side of the outer edge 40)” when viewed from the Z direction, and means a maximum value of different distances in a case where the distance differs depending on the side. As an example, the distance between the outer edge 42a of the light receiving region 42 and the outer edge 40 of the light receiving element 4 when viewed from the Z direction is about 500 μm, and the distance between the outer edge 40 of the light receiving element 4 and the outer edge 80 of the optical filter member 8 when viewed from the Z direction is about 200 μm.

As illustrated in FIGS. 1 and 2, the distance between the outer edge 42a of the light receiving region 42 and the outer edge 40 of the light receiving element 4 when viewed from the Z direction is larger than the thickness of the light receiving element 4 in the Z direction. As an example, the distance between the outer edge 42a of the light receiving region 42 and the outer edge 40 of the light receiving element 4 is about 500 μm, and the thickness of the light receiving element 4 in the Z direction is about 50 μm. The distance between the outer edge 42a of the light receiving region 42 and the outer edge 80 of the optical filter member 8 when viewed from the Z direction is larger than the thickness of the light transmitting member 7 in the Z direction. As an example, the distance between the outer edge 42a of the light receiving region 42 and the outer edge 80 of the optical filter member 8 when viewed from the Z direction is about 700 μm, and the thickness of the light transmitting member 7 is about 300 μm.

As illustrated in FIG. 1, when viewed from the Z direction, an outer edge 26a of a light transmitting region 26 in the window portion 23 is positioned outside the outer edge 80 of the optical filter member 8. The light transmitting region 26 is a region of the window portion 23 that can transmit light including the light to be detected along the Z direction. In the present embodiment, the light transmitting region 26 is a region positioned inside the adhesive member 25 when viewed from the Z direction in the window portion 23.

As illustrated in FIGS. 1 and 2, a plurality of chip capacitors 15 and a plurality of chip capacitors 16 are disposed on the bottom wall portion 21 in the package 2. Each chip capacitor 15 is a chip capacitor for the circuit element 3, and is electrically and physically connected to the corresponding terminal 24 by a conductive resin member. Each chip capacitor 16 is a chip capacitor for the light receiving element 4, and is electrically and physically connected to the corresponding terminal 24 by a solder member.

In the photodetector 1 having the above configuration, when light including the light to be detected is transmitted through the window portion 23 and is incident on the optical filter member 8, only the light to be detected is transmitted through the optical filter film 82. The light to be detected transmitted through the optical filter film 82 is transmitted through the adhesive member 9 and the light transmitting member 7 and is incident on the light receiving region 42 of the light receiving element 4. A detection signal generated in each light receiving unit 41 by the incidence of the light to be detected on the light receiving region 42 is output to the outside via each wiring of each bump 5, the circuit element 3, each wire 12, and the bottom wall portion 21.

### Method for Manufacturing Photodetector

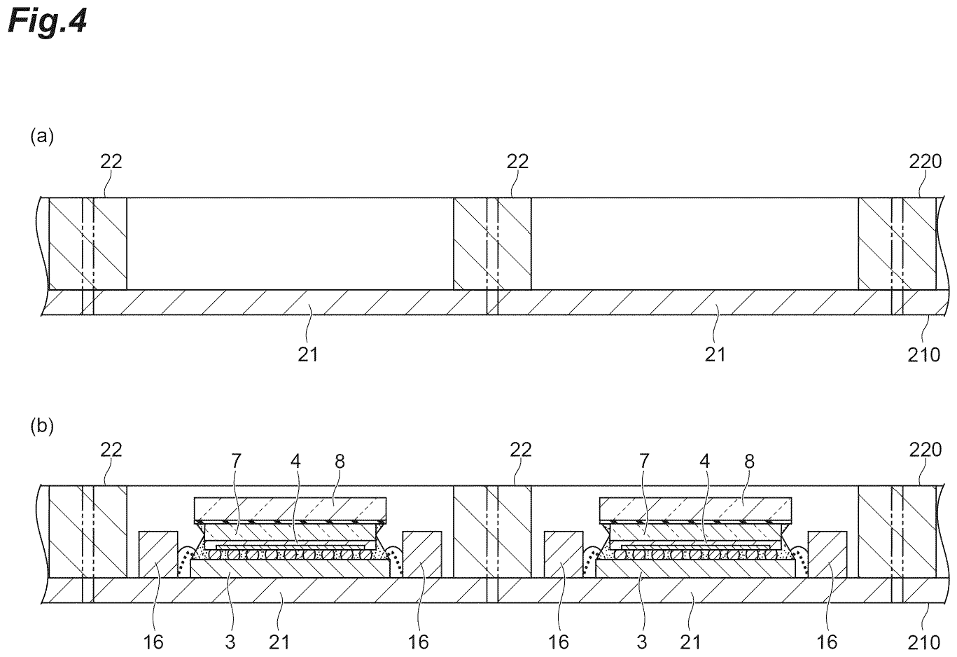

A method for manufacturing the photodetector 1 will be described. First, as illustrated in (a) of FIG. 4, a side wall substrate 220 adheres to a bottom wall substrate 210 by an adhesive member (not illustrated). The bottom wall substrate 210 includes a portion to be each of the plurality of bottom wall portions 21 disposed two-dimensionally. The side wall substrate 220 includes a portion to be each of the plurality of side wall portions 22 disposed two-dimensionally. Subsequently, as illustrated in (b) of FIG. 4, the circuit element 3, the light receiving element 4 and the light transmitting member 7 bonded to each other, the optical filter member 8, the plurality of chip capacitors 15, the plurality of chip capacitors 16, and the like are implemented on the portions to be the plurality of bottom wall portions 21 via openings of the portions to be the plurality of side wall portions 22.

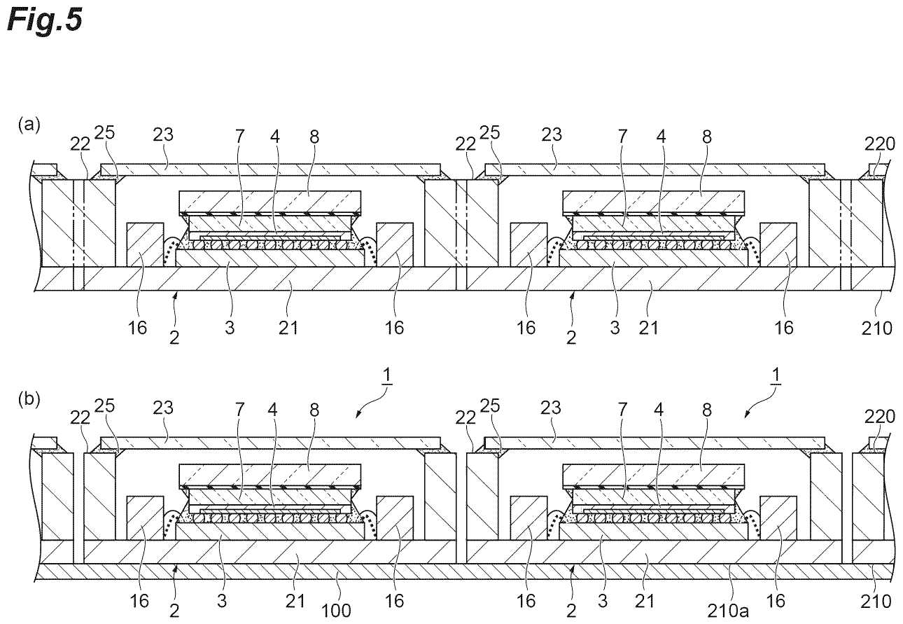

Subsequently, as illustrated in (a) of FIG. 5, the window portion 23 adheres to the portion to be each of the plurality of side wall portions 22 by the adhesive member 25 so as to close the opening of the portion to be each of the plurality of side wall portions 22. At this time, since gas is released from a space inside the portion to be each of the plurality of side wall portions 22 via the through-hole 21c (see FIG. 1) formed in the portion to be each of the plurality of bottom wall portions 21, the window portion 23 is reliably bonded to the portion to be each of the plurality of side wall portions 22.

Subsequently, as illustrated in (b) of FIG. 5, in a state where a dicing tape 100 is attached to a front surface 210a of the bottom wall substrate 210 opposite to the side wall substrate 220, the bottom wall substrate 210 and the side wall substrate 220 bonded to each other are diced for each portion to be each of a plurality of packages 2. At this time, since the through-hole 21c (see FIG. 1) formed in the portion to be each of the plurality of bottom wall portions 21 is closed by the dicing tape 100, entry of dicing water into the space inside the portion to be each of the plurality of packages 2 is prevented.

Subsequently, a plurality of photodetectors 1 are picked up from the dicing tape 100. As a result, the plurality of photodetectors 1 are obtained. Note that, each photodetector 1 is inspected in the package 2 via the window portion 23. The inspection is, for example, confirmation of the presence or absence of a foreign substance by a camera or the like.

### Operations and Effects

In the photodetector 1, the light receiving element 4 is disposed on the bottom wall portion 21 in the package 2, and the optical filter member 8 is disposed on the light receiving element 4 in the package 2. As a result, for example, a degree of freedom of a shape of the package 2 is secured such that it is not necessary to reduce a size of the opening closed by the window portion 23 in the package 2. Further, in the photodetector 1, when viewed from the Z direction, the outer edge 40 of the light receiving element 4 is positioned inside the outer edge 80 of the optical filter member 8. As a result, a probability that light is incident on the light receiving element 4 via the optical filter member 8 increases. As described above, according to the photodetector 1, it is possible to accurately detect the light to be detected while securing the degree of freedom of the shape of the package 2.

In the photodetector 1, when viewed from the Z direction, the distance between the outer edge 42a of the light receiving region 42 and the outer edge 40 of the light receiving element 4 is larger than the distance between the outer edge 40 of the light receiving element 4 and the outer edge 80 of the optical filter member 8. As a result, light obliquely incident on the light receiving element 4 without passing through the optical filter member 8 can be prevented from being incident on the light receiving region 42, and the light to be detected can be detected more accurately.

In the photodetector 1, when viewed from the Z direction, the outer edge 70 of the light transmitting member 7 is positioned inside the outer edge 80 of the optical filter member 8. As a result, it is possible to prevent light obliquely incident on the light transmitting member 7 without passing through the optical filter member 8 from being guided by the light transmitting member 7 and being incident on the light receiving element 4, and it is possible to more accurately detect the light to be detected.

In the photodetector 1, the adhesive member 9 is disposed between the light transmitting member 7 and the optical filter member 8. As a result, in a case where an adhesive (having fluidity and cured after adhesion) is used as the adhesive member 9 at the time of manufacturing the photodetector 1, since the adhesive is likely to remain at a corner portion between the side surface 7c of the light transmitting member 7 and the front surface 8b of the optical filter member 8, the optical filter member 8 can be firmly fixed on the light transmitting member 7 while suppressing unnecessary spread of the adhesive.

In the photodetector 1, the circuit element 3 is disposed between the bottom wall portion 21 and the light receiving element 4. As a result, a size of the photodetector 1 when viewed from the Z direction can be reduced.

In the photodetector 1, the circuit element 3 and the light receiving element 4 are electrically and physically connected by the plurality of bumps 5. Thus, it is possible to improve responsiveness of the electric signal between the circuit element 3 and the light receiving element 4.

In the photodetector 1, the resin member 6 disposed between the circuit element 3 and the light receiving element 4 reaches the side surface 7c of the light transmitting member 7 via the side surface 4c of the light receiving element 4. As a result, not only fixation between the circuit element 3 and the light receiving element 4 but also fixation between the light receiving element 4 and the light transmitting member 7 can be maintained in a reliable state.

In the photodetector 1, the wire 11 extending between the terminal 24 of the bottom wall portion 21 and the terminal 31 of the circuit element 3 is covered with the resin member 13. As a result, a high voltage can be applied to the wire 11 while suppressing unintended energization.

In the photodetector 1, the wire 11 is a wire for applying a power supply voltage to the light receiving element 4. As a result, it is possible to apply the power supply voltage to the light receiving element 4 while suppressing the unintended energization of the wire 11.

In the photodetector 1, the optical filter member 8 includes the light transmitting substrate 81 and the optical filter film 82 formed on the front surface 81b of the light transmitting substrate 81 on the light transmitting member 7 side. As a result, for example, as compared with a case where the optical filter film 82 is formed on the front surface 81a of the light transmitting substrate 81 opposite to the light transmitting member 7, a probability that light is incident on the light receiving element 4 via the optical filter film 82 can be increased, and the light to be detected can be detected more accurately.

In the photodetector 1, when viewed from the Z direction, the outer edge 26a of the light transmitting region 26 in the window portion 23 is positioned outside the outer edge 80 of the optical filter member 8. As a result, visibility in the package 2 via the window portion 23 can be improved, and the inspection in the package 2 can be appropriately performed.

In the photodetector 1, the distance between the outer edge 42a of the light receiving region 42 and the outer edge 40 of the light receiving element 4 when viewed from the Z direction is larger than the thickness of the light receiving element 4 in the Z direction. As a result, light obliquely incident on the light receiving element 4 without passing through the optical filter member 8 can be prevented from being incident on the light receiving region 42, and the light to be detected can be detected more accurately.

In the photodetector 1, the distance between the outer edge 42a of the light receiving region 42 and the outer edge 80 of the optical filter member 8 when viewed from the Z direction is larger than the thickness of the light transmitting member 7 in the Z direction. As a result, light obliquely incident on the light receiving element 4 without passing through the optical filter member 8 can be prevented from being incident on the light receiving region 42, and the light to be detected can be detected more accurately.

In the photodetector 1, as compared with a case where the window portion 23 is formed by the optical filter member 8 in the package 2, since the size of the optical filter member 8 that is generally expensive can be reduced, the cost of the photodetector 1 can be reduced. Here, in order to reduce the size of the optical filter member 8, it is also conceivable to form the optical filter film 82 on the light transmitting member 7. However, when the optical filter film 82 is integrally formed on the second wafer including the portion to be each of the plurality of light transmitting members 7 disposed two-dimensionally, the second wafer may be warped, and it may be difficult to bond the second wafer to the first wafer including the portion to be each of the plurality of light receiving elements 4 disposed two-dimensionally. Therefore, in the photodetector 1, a configuration in which the optical filter film 82 is formed on the light transmitting substrate 81 having a thickness larger than the thickness of the light transmitting member 7 is adopted.

In the photodetector 1, the space inside the package 2 and the space outside the package 2 are communicated by the through-hole 21c formed in the bottom wall portion 21. As a result, it is possible to prevent a gap from being generated between the side wall portion 22 and the window portion 23 due to the expansion of the gas in the package 2. In addition, it is possible to prevent dew condensation from occurring in the package 2 due to a temperature difference between the space inside the package 2 and the space outside the package 2.

### Modifications

The present disclosure is not limited to the above embodiment. For example, the circuit element 3 and the light receiving element 4 may be electrically and physically connected to each other by direct bonding. Accordingly, it is possible to improve the responsiveness of the electric signal between the circuit element 3 and the light receiving element 4. In addition, the adhesive member 9 may not be disposed between the light transmitting member 7 and the optical filter member 8, and the optical filter member 8 may be fixed to the light transmitting member 7 by an adhesive film or the like.

In addition, the circuit element 3 may not be disposed between the bottom wall portion 21 and the light receiving element 4, and in this state, the light receiving element 4 may be disposed on the bottom wall portion 21. In addition, the light transmitting member 7 may not be disposed between the light receiving element 4 and the optical filter member 8, and in this state, the optical filter member 8 may be disposed on the light receiving element 4.

In addition, the light receiving element 4 may be a front-incident optical semiconductor element in which the plurality of light receiving units 41 are two-dimensionally disposed along the front surface 4a. In addition, the plurality of light receiving units 41 may be one-dimensionally disposed regardless of whether the light receiving element 4 is the back-incident optical semiconductor element or the front-incident optical semiconductor element.

In addition, in the optical filter member 8, the optical filter film 82 may be formed on the front surface 81a of the light transmitting substrate 81 opposite to the light transmitting member 7. In addition, when viewed from the Z direction, the outer edge of the light transmitting member 7 may not coincide with the outer edge of the light receiving element 4. In addition, when viewed from the Z direction, the outer edge 26a of the light transmitting region 26 in the window portion 23 may not be positioned outside the outer edge 80 of the optical filter member 8. In addition, the side wall portion 22 may be formed integrally with the bottom wall portion 21.

In addition, when viewed from the Z direction, the distance between the outer edge 42a of the light receiving region 42 and the outer edge 40 of the light receiving element 4 may be equal to or less than the distance between the outer edge 40 of the light receiving element 4 and the outer edge 80 of the optical filter member 8. In addition, the distance between the outer edge 42a of the light receiving region 42 and the outer edge 40 of the light receiving element 4 when viewed from the Z direction may be equal to or less than the thickness of the light receiving element 4 in the Z direction. In addition, the distance between the outer edge 42a of the light receiving region 42 and the outer edge 80 of the optical filter member 8 when viewed from the Z direction may be equal to or less than the thickness of the light transmitting member 7 in the Z direction. In any case, when viewed from the Z direction, the outer edge 42a of the light receiving region 42 is positioned inside the outer edge 40 of the light receiving element 4, and thus, the light obliquely incident on the light transmitting member 7 and/or the light receiving element 4 without passing through the optical filter member 8 is prevented from being incident on the light receiving region 42. In addition, in any case, when viewed from the Z direction, the outer edge 42a of the light receiving region 42 may overlap the outer edge 40 of the light receiving element 4.

### REFERENCE SIGNS LIST

1 photodetector
2 package
3 circuit element
4 light receiving element
4c side surface
5 bump
6 resin member (first resin member)
7 light transmitting member
7c side surface
8 optical filter member
9 adhesive member
11 wire
13 resin member (second resin member)
21 bottom wall portion
23 window portion
24 terminal
26 light transmitting region
26a outer edge
31 terminal
40 outer edge
41 light receiving unit
42 light receiving region
42a outer edge
70 outer edge
80 outer edge
81 light transmitting substrate
81b front surface (front surface on light transmitting member side in light transmitting substrate)
82 optical filter film.

1: A photodetector, comprising:
a package having a bottom wall portion and a window portion facing each other;
a light receiving element disposed on the bottom wall portion in the package;
a light transmitting member disposed on the light receiving element in the package; and
an optical filter member disposed on the light transmitting member in the package, wherein
the light receiving element includes a light receiving region including a plurality of light receiving units, and
when viewed from a direction in which the bottom wall portion and the window portion face each other, an outer edge of the light receiving element is positioned inside an outer edge of the optical filter member.

2: The photodetector according to claim 1, wherein, when viewed from the direction in which the bottom wall portion and the window portion face each other, a distance between an outer edge of the light receiving region and the outer edge of the light receiving element is larger than a distance between the outer edge of the light receiving element and the outer edge of the optical filter member.

3: The photodetector according to claim 1, wherein, when viewed from the direction in which the bottom wall portion and the window portion face each other, an outer edge of the light transmitting member is positioned inside the outer edge of the optical filter member.

4: The photodetector according to claim 3, further comprising: an adhesive member disposed between the light transmitting member and the optical filter member.

5: The photodetector according to claim 1, further comprising: a circuit element disposed between the bottom wall portion and the light receiving element.

6: The photodetector according to claim 5, further comprising: a plurality of bumps electrically and physically connecting the circuit element and the light receiving element.

7: The photodetector according to claim 6, further comprising:
a first resin member disposed between the circuit element and the light receiving element, wherein
the first resin member reaches a side surface of the light transmitting member via a side surface of the light receiving element.

8: The photodetector according to claim 5, wherein the circuit element and the light receiving element are electrically and physically connected by direct bonding.

9: The photodetector according to claim 5, further comprising:
a wire extending between a terminal of the bottom wall portion and a terminal of the circuit element; and
a second resin member covering the wire.

10: The photodetector according to claim 9, wherein the wire is a wire for applying a power supply voltage to the light receiving element.

11: The photodetector according to claim 1, wherein the optical filter member includes a light transmitting substrate and an optical filter film formed on a front surface of the light transmitting substrate on the light transmitting member side.

12: The photodetector according to claim 1, wherein, when viewed from the direction in which the bottom wall portion and the window portion face each other, an outer edge of a light transmitting region in the window portion is positioned outside the outer edge of the optical filter member.

13: The photodetector according to claim 1, wherein a distance between an outer edge of the light receiving region and the outer edge of the light receiving element when viewed from the direction in which the bottom wall portion and the window portion face each other is larger than a thickness of the light receiving element in the direction in which the bottom wall portion and the window portion face each other.

14: The photodetector according to claim 1, wherein a distance between an outer edge of the light receiving region and the outer edge of the optical filter member when viewed from the direction in which the bottom wall portion and the window portion face each other is larger than a thickness of the light transmitting member in the direction in which the bottom wall portion and the window portion face each other.
